(19) United States
(12) Patent Application Publication
(10) Pub. No.: US 2020/0083065 A1
(43) Pub. Date: Mar. 12, 2020

(54) PROCESS FOR TREATING AN SOI SUBSTRATE IN A SINGLE WAFER CLEANER

(71) Applicant: Soitec, Bernin (FR)

(72) Inventors: Laurent Viravaux, Corenc (FR); Sébastien Ledrappier, La Tronche (FR)

(21) Appl. No.: 16/560,739

(22) Filed: Sep. 4, 2019

(30) Foreign Application Priority Data
Sep. 11, 2018 (FR) 1858118

(51) Int. Cl. H01L 21/67; H01L 21/02; B08B 3/08

(52) U.S. Cl. CPC H01L 21/67051; B08B 3/08; H01L 21/02057

(57) ABSTRACT

A method of treating an SOI substrate in a single wafer cleaner includes gripping and rotating the substrate using a system, and dispensing a first liquid solution from a first nozzle in the form of a spray of droplets onto a front face of the SOI substrate. The kinetic energy per unit area of the droplets is lower than or equal to 30 joules/m².

### PRIORITY CLAIM

This application claims the benefit of the filing date of French Patent Application Serial No. FR1858118, filed Sep. 11, 2018, for “PROCESS FOR TREATING AN SOI SUBSTRATE IN A SINGLE WAFER CLEANER,” the contents of which are incorporated herein in their entirety by this reference.

### TECHNICAL FIELD

The present disclosure relates to the field of microelectronics. In particular, it relates to a process for cleaning SOI (silicon-on-insulator) substrates using a single wafer cleaner.

### BACKGROUND

Single wafer cleaners (SWCs) are commonly used in microelectronic processes for their high performance in cleaning wafers of large diameters (in particular 300 mm). Specifically, they make it possible to limit certain defects at the edges of wafers, as often associated with batch cleaners, which work via series of immersions in chemical baths. The risk of cross-contamination between wafers in one and the same batch is also lower with single wafer cleaners. Lastly, these cleaners allow greater flexibility in the selection of cleaning sequences, which may be adapted for each wafer if required.

In a single wafer cleaner, the wafer is held by fingers around its periphery and moved by rotation throughout the various cleaning or thinning (chemical etching) sequences. Arms for dispensing chemical solutions and/or rinsing solutions are configured so as to move over the wafer; the dispensed solution is spread by centrifugal effect over the entire surface of the wafer and thrown over the edge of the wafer. A plurality of tapered collectors, arranged in a space that is peripheral to the wafer allows the chemical solutions, which are dispensed consecutively in the cleaning or thinning sequences, to be collected selectively. The collectors are capable of changing altitude with respect to the wafer, and thus each collector may be positioned so as to collect a particular solution as it is thrown over the edge of the wafer, thereby avoiding the mixing of incompatible chemical solutions.

A single wafer cleaner may for example be used for the final cleaning and/or thinning of the silicon surface layer of an SOI wafer, in particular of an FDSOI (fully depleted SOI) wafer, which has a very thin silicon layer (typically between a few nanometers and a few tens of nanometers).

The applicant observed a 500% increase in the number of HF defects on FDSOI wafers, in which the thickness of the surface silicon layer is around 10 to 12 nm, undergoing final cleaning in a single wafer cleaner in comparison with similar cleaning in a chemical-bath multi-wafer cleaner (around two defects per wafer). While these figures are liable to vary with the properties of the surface layer, the increase in HF defects remains significant and there appears to be a need to improve the processes for cleaning or etching SOI substrates in a single wafer cleaner.

It is recalled that an HF defect corresponds to a surface or bulk fault in the silicon surface layer, providing an accessway through the surface layer down to the subjacent oxide layer of the SOI substrate. These faults are revealed through immersion of the wafer in a solution of hydrofluoric (HF) acid, which, by penetrating through the surface layer, attacks the oxide layer and makes the defect apparent.

### BRIEF SUMMARY

The present disclosure aims to overcome all or some of the aforementioned drawbacks. Embodiments of the present disclosure relate to a process for cleaning and/or thinning SOI wafers in a single wafer cleaner. In particular, embodiments of the present disclosure provide a solution for decreasing HF defects in FDSOI substrates after cleaning in a single wafer cleaner.

The present disclosure relates to a process for treating an SOI substrate in a single wafer cleaner, the cleaner comprising:
a system for gripping the substrate that is capable of performing a rotating movement; and
a first nozzle for dispensing a first solution in the form of a spray over a front face of the substrate.

The process is noteworthy in that the kinetic energy per unit area of the droplets is lower than or equal to 30 joules/m².

According to other advantageous and non-limiting features of the present disclosure, which may be implemented alone or in any technically feasible combination:
the spray is formed from the mixture of the first liquid solution exhibiting a flow rate of between 0.1 liter per minute and 0.2 liter per minute, and of nitrogen gas exhibiting a flow rate of less than or equal to 70 liters per minute, preferably less than or equal to 60 liters per minute;
the single wafer cleaner comprises a second nozzle for dispensing a second solution over a back face of the substrate, and the second solution is dispensed over the back face of the substrate only when the front face is protected via the dispensing of the first solution or via the formation of a nitrogen cushion;
the single wafer cleaner comprises a third nozzle for dispensing a third solution in the form of a low- or medium-pressure liquid jet over the front face of the substrate, and the second solution is dispensed over the back face of the substrate only when the front face is protected via the dispensing of the third solution or of the first solution or via the formation of a nitrogen cushion;
the nitrogen cushion is formed between the front face of the substrate and a screen plate, which is positioned parallel to the front face and a short distance away therefrom, and is capable of giving off nitrogen under pressure;
the dispensing of a solution over the back face of the substrate is synchronized with the dispensing of a solution over the front face of the substrate;
the single wafer cleaner comprises a plurality of tapered collectors that are arranged in a space that is peripheral to the substrate so as to collect the solutions after dispensing, and the position of each collector is changed only when the speed of the rotating movement of the system for gripping the substrate is lower than or equal to 600 revolutions per minute.

### BRIEF DESCRIPTION OF THE DRAWINGS

Other features and advantages of the present disclosure will become apparent from the following detailed description, with reference to the appended figures, in which:

FIGS. 1 and 2 show diagrams of a single wafer cleaner;

FIG. 3 is a table showing a standard treatment applied to a substrate in a single wafer cleaner;

FIG. 4 shows stacked maps of the front face of a plurality of FDSOI substrates treated according to the standard treatment in a single wafer cleaner;

FIGS. 5, 6, and 7 are tables showing a treatment applied to a substrate in a single wafer cleaner according to a first, a second and a third embodiment of the process according to the present disclosure, respectively; and

FIGS. 8, 9, and 10 show stacked maps of the front face of a plurality of FDSOI substrates treated according to the first, the second and the third embodiment of the process according to the present disclosure, respectively.

### DETAILED DESCRIPTION

The present disclosure relates to a process for treating an SOI substrate in a single wafer cleaner (SWC).

Such a cleaner comprises a treatment chamber in which a system (not shown) for gripping the substrate 1 to be treated is located. Typically, but not limitingly, the system includes at least three fingers for mechanically holding the substrate 1 around its periphery. The gripping system is capable of performing a rotating movement, which is transmitted to the substrate 1 over the course of the sequences of treatment.

The single wafer cleaner also comprises at least one nozzle 10, 30 for dispensing at least one solution over the front face 1a of the substrate 1. It is noted that the front face 1a of the substrate 1 is often referred to as the “active” face. For an SOI substrate in particular, the active face is the free face of the silicon surface layer. The nozzle 10, 30 is typically carried by a movable arm that is capable of positioning the nozzle 10, 30 substantially facing the center of the substrate 1 and/or capable of moving over the substrate, for example by moving back and forth in circular arcs. The solution distributed by the nozzle 10, 30 is spread over the entire surface of the substrate 1 by centrifugal effect.

Various types of liquid solutions may be dispensed over the front face 1a of the substrate 1. By way of example, the following acid or basic chemical solutions may be cited: hydrofluoric acid (HF), hydrochloric acid (HCl), sulfuric acid (H₂SO₄), ozone (O₃), SC2—Standard Clean 2 (HCL/H₂O₂/H₂O), SC1—Standard Clean 1 (NH₃/H₂O₂/H₂O)) with variable concentrations of the compounds, or rinsing solutions (ultrapure water).

They may be dispensed in the form of a low-pressure or medium-pressure liquid jet (typically at 0.5 to 2.5 /min) or in the form of a spray. The spray is formed by mixing a gas at high pressure with the liquid of the desired solution at low pressure. The gas used is typically nitrogen.

For dispensing over the front face 1a of the substrate 1, the single wafer cleaner comprises in particular a first nozzle 10 allowing a first solution to be dispensed in the form of a spray. Throughout the rest of this description, the term “first solution” will refer to any solution dispensed over the front face 1a of the substrate 1 in the form of a spray. The first solution could be chosen from the various liquid solutions mentioned above.

Spray-dispensing is conventionally used to remove particular contaminants effectively from the surface of the substrate 1. For cleaning substrates made of silicon, whether exposed or featuring uniform layers, whether structured or without structuring, the spray is usually formed of a mixture of nitrogen, having a flow rate of between 0.5 l/min and 250 /min, and of liquid (the first solution, which could, for example, be a solution of SC1) having a flow rate of between 50 ml/min and 300 ml/min.

The single wafer cleaner advantageously comprises at least one nozzle 20 for dispensing at least one solution over the back face 1b of the substrate 1, opposite its front face 1a. This nozzle 20 may be carried by a fixed arm that is capable of positioning the nozzle substantially facing the center of the substrate 1, on the back face 1b. Alternatively, the arm may be movable, capable of positioning the nozzle 20 substantially facing the center of the substrate 1 and/or of moving under the substrate, for example by moving back and forth in circular arcs. The solution distributed by the nozzle 20 is spread over the entire back face 1b of the substrate 1 by centrifugal effect.

Various types of liquid solutions may be dispensed over the back face 1b of the substrate 1, in particular the solutions mentioned above for dispensing over the front face 1a.

Typically, they may be dispensed in the form of a low- or medium-pressure liquid jet (typically at 0.5 to 2.5 /min).

For dispensing over the back face 1b of the substrate 1, the single wafer cleaner comprises in particular a second nozzle 20 allowing a second solution to be dispensed. Throughout the rest of this description, the term “second solution” will refer to any solution dispensed over the back face 1b of the substrate 1.

Advantageously, the single wafer cleaner comprises at least one other nozzle 30 (referred to as the “third nozzle”) allowing a solution in the form of a low-pressure or medium-pressure liquid jet to be dispensed over the front face 1a of the substrate 1. Throughout the rest of this description, the term “third solution” will refer to any solution dispensed over the front face 1a of the substrate 1 in the form of a low- or medium-pressure liquid jet. The third solution could be chosen from the various liquid solutions mentioned above.

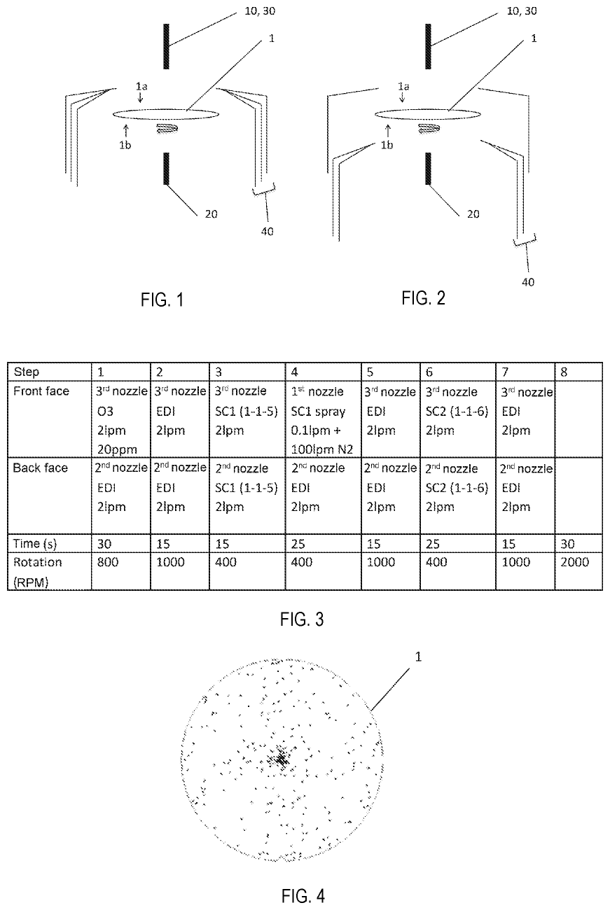

The single wafer cleaner advantageously comprises a plurality of collectors 40 that are arranged in a space that is peripheral to the substrate 1 (FIG. 1) and are intended to selectively collect the first, second and/or third solutions used for treating the substrate 1. Each collector 40 is tapered in shape and is capable of changing altitude with respect to the substrate 1; each collector 40 may thus be positioned so as to collect a particular solution as it is thrown over the edge of the wafer (FIG. 2).

By way of example, a cleaning sequence such as:
Ozone (O₃)
Rinsing (deionized water (DIW))
SC1 or SC2
SC1 spray (dispensed in the form of a spray)
Rinsing (DIW)
SC2
Rinsing (DIW)

may be used to clean away organic, particulate and metal contaminants from SOI substrates. The table of FIG. 3 contains the standard parameters of such a sequence according to the prior art, for example applied to silicon substrates that are exposed or that feature uniform layers (such as oxides for example). The proportions of the various constituents —NH₃/H₂O₂/H₂O in the case of SC1 and HCl/H₂O₂/H₂O in the case of SC2—are given between parentheses in FIG. 3, along with the flow rates through the first 10, second 20 and third 30 nozzles.

In steps 1, 2, 3, 5, 6 and 7, the third nozzle 30 dispenses over the front face 1a of the substrate 1 in the form of a low- or medium-pressure liquid jet (flow rate of about 2 liters per minute).

In step 4, the SC1 solution is dispensed in the form of a spray from the first nozzle 10; the spray is formed from a mixture of the first solution (SC1 in this example), the flow rate of which is 0.05 liters per minute, and of nitrogen gas, the flow rate of which is 100 liters per minute.

The applicant applied this standard sequence to SOI substrates 1 in the single wafer cleaner. As is well known per se, an SOI substrate comprises a silicon surface layer and a buried silicon oxide layer, which are positioned on a carrier substrate. An SOI substrate may be fabricated using the SmartCut™ process, which is based on implantation of light hydrogen and/or helium ions into a donor substrate and bonding, for example by molecular adhesion of this donor substrate to the carrier substrate, a layer of silicon oxide being intercalated between these two substrates. A detaching step then allows a thin surface layer to be separated from the donor substrate, level with the weakened plane defined by the implantation depth of the ions. Finishing steps, possibly including high-temperature heat treatments, lastly give the active layer the required surface and crystal quality. This process is particularly suitable for fabricating very thin silicon surface layers. The steps of finishing the SOI substrate also include sequences of cleaning and/or thinning the silicon surface layer.

In particular, the standard sequence was applied to FDSOI substrates including a silicon surface layer and a buried silicon oxide, the thicknesses of which were 10 nm and 30 nm, respectively.

Such a cleaning sequence makes it possible for silicon substrates, for example, to clean the front face 1a and the back face 1b of the SOI substrate 1. The cleaning sequence may also allow the silicon surface layer to be thinned by a few nanometers as the SC1 solution is dispensed over the front face 1a so as to remove surface defects or to reach an exact layer thickness.

FIG. 4 shows stacked maps of the front face 1a of about 30 FDSOI substrates after treatment according to the standard sequence in the single wafer cleaner and after HF defects have been revealed. The average number of HF defects (represented by dots on the stacked map) on each wafer is around five times greater after treatment with respect to a similar treatment in a chemical-bath multi-wafer cleaner.

It should be noted that the maps are obtained using instruments for measuring defects (threshold 0.1 micron) that are based on dark-field microscopy, e.g. KLA-TENCOR SURF SCAN SP® (registered trademark).

The treatment process according to the present disclosure is noteworthy in that the step of spray-dispensing a first solution over the front face of the FDSOI substrate is carried out such that the kinetic energy per unit area of the droplets in the spray is lower than or equal to 30 joules/m². This kinetic energy per unit area corresponds to the energy delivered by a droplet as it hits the wafer 1. Its value is calculated on the basis of the following equation:

$$E = \frac{{mv}^{2}}{2 π {r}^{2}}$$

where m is the mass of the droplet, v is its velocity and r is its radius.

Reference could be made to the systems and techniques known from the prior art for characterizing the exit velocity of a droplet in a spray.

For example, in the single wafer cleaner used here, with a nitrogen flow rate of 45 liters per minute for the spray-dispensing, the kinetic energy of the droplet is about 3.35E-9 J. The impact area of the droplet is about 3.14E-10 m². This therefore gives an energy per unit area of about 10 J/m².

Specifically, the applicant observed that the spraying of these droplets over the front face 1a of an SOI substrate 1 was liable to mechanically damage the silicon surface layer, and increasingly so with decreasing thickness of this layer, in particular for thicknesses of less than 50 nm. The damage manifests as micro-holes or crystal defects through the silicon surface layer, which are the cause of the increase in HF defects.

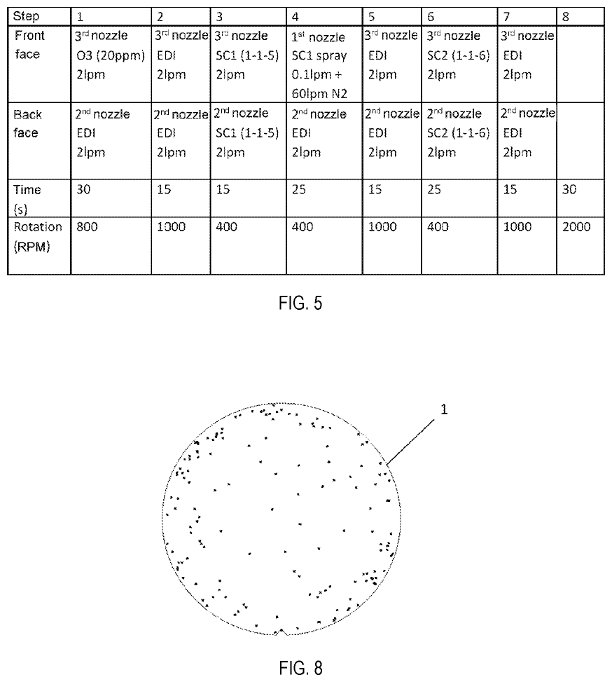

The table of FIG. 5 gives the main parameters of a first embodiment of the process according to the present disclosure. In step 4, the first solution, SC1, is dispensed in the form of a spray formed from the mixture of:
the first solution, the flow rate of which is between 0.1 liter per minute and 0.2 liter per minute, preferably between 0.15 and 0.2 liter per minute; and
and nitrogen gas, the flow rate of which is less than or equal to 70 liters per minute, preferably less than or equal to 60 liters per minute.

In this configuration, the kinetic energy per unit area of the droplets reaching the front face 1a of the SOI substrate 1 is lower than or equal to 30 joules/m², which avoids or substantially decreases damage to the silicon surface layer.

The example used here is that of spray dispensing a first, SC1-type solution, but the nature of the solution is unimportant and it could in particular be chosen from the various types of solutions mentioned above. In any case, the process according to the present disclosure makes provision for the energy per unit area of the droplets in the spray reaching the front face 1a of the SOI substrate 1 to be lower than or equal to 30 joules/m² so as to limit mechanical damage to the silicon surface layer

Preferably, the kinetic energy per unit area of the droplets in the spray will be chosen to be higher than 2 joules/m² so as to keep the effectiveness of cleaning the surface of the substrate high.

FIG. 8 shows stacked maps of the front face of about 30 FDSOI substrates after application of the process according to the first embodiment in the single wafer cleaner and after HF defects have been revealed. The average number of HF defects on each substrate has decreased by around 30 to 40% with respect to FIG. 4, which represents a significant improvement over the standard sequence.

Advantageously, during the process, a second solution is dispensed over the back face 1b of the substrate 1 only when the front face 1a of the substrate 1 is protected via the dispensing of a first or of a third solution.

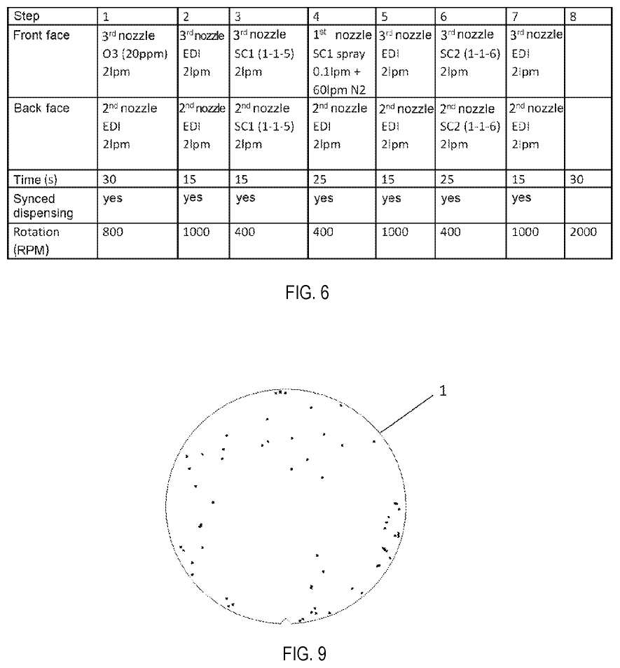

The table of FIG. 6 gives the main parameters of a second embodiment of the process according to the present disclosure. In this second embodiment, a second solution is not dispensed (over the back face 1b) if the dispensing of a first or of a third solution (over the front face 1a) is not underway. The second embodiment further comprises the optimized parameters of step 4 mentioned in the first embodiment.

The applicant identified that the liquid thrown over the edges of the substrate 1 from the back face 1b (second solution) could splash back onto the front face 1a of the substrate 1, in particular by splashing off the tapered walls of the collector 40. If the silicon surface layer is exposed, this splashback is liable to damage it mechanically. Such damage again manifests as micro-holes or crystal defects through the silicon surface layer, and are liable to cause HF defects.

Conversely, if the silicon surface layer is covered by a liquid layer (while the dispensing of a first solution or of a third solution is underway), splashback has no deleterious effect on the surface layer.

According to this second embodiment, the dispensing over the front face (from the first nozzle 10 or from the third nozzle 30) and the dispensing over the back face (from the second nozzle 20) take place at the same time. This is known as synchronized dispensing. This involves taking into consideration the time needed to transport the dispensed solutions to each of the faces 1a, 1b simultaneously, the time needed depending primarily on the length of the pipes for supplying the solutions. This synchronization allows the time during which one of the faces 1a, 1b remains unprotected by one of the dispensed solutions to be limited or eliminated, thus limiting the risk of the unprotected face being damaged. By synchronizing the dispensing over the front face and the dispensing over the back face, the variability of the exit angle of the first, second and/or third solutions from the edges of the substrate 1 is also limited, thereby decreasing the risk of splashback off the tapered walls of the collectors 40.

FIG. 9 shows stacked maps of the front face of about 30 FDSOI substrates after application of the process according to the second embodiment in the single wafer cleaner and after HF defects have been revealed. The average number of HF defects on each wafer is decreased by around 20% with respect to FIG. 8 (first embodiment) , which represents a substantial improvement over the first embodiment of the process and a significant improvement over the standard sequence.

It should be noted that synchronizing the dispensing over the front face 1a and over the back face 1b could be implemented independently of the optimization of the dispensing of the first solution over the front face 1a in the form of a spray.

According to one variant of the second embodiment, the front face 1a of the substrate 1 is protected while a second solution is dispensed over the back face 1b of the substrate 1 via the formation of a nitrogen cushion. Preferably, the nitrogen cushion is formed between the front face of the SOI substrate and a screen plate, positioned parallel to the front face and a short distance, typically about 1 to 2 mm, away therefrom; the screen plate is capable of giving off a stream of nitrogen under pressure, which prevents projections from the edges of the substrate 1 from returning to the front face 1a.

In the same way as a liquid layer protects the silicon surface layer from splashback resulting from the dispensing over the back face, a gas layer also allows this deleterious effect to be limited.

Advantageously, throughout the process, the position of each collector 40 of the plurality of collectors of the single wafer cleaner is changed when the speed of the rotating movement of the system for gripping the substrate 1 is lower than or equal to 600 revolutions per minute.

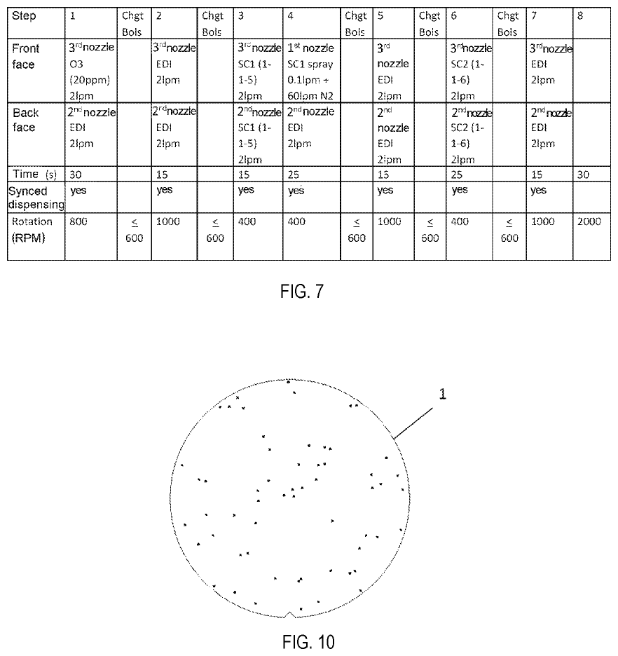

The table of FIG. 7 gives the main parameters of this third embodiment of the process according to the present disclosure. This third embodiment includes the optimizations mentioned in the first and second embodiments and includes an action of limiting the speed of rotation of the substrate 1 when the position of a collector 40 is changed. This limiting action makes it possible to limit splashback off the tapered walls of the collector 40 onto the front face 1a of the substrate 1.

FIG. 10 shows stacked maps of the front face of about 30 FDSOI substrates after application of the process according to the third embodiment in the single wafer cleaner and after HF defects have been revealed. The average number of HF defects on each wafer is decreased by around 20% with respect to FIG. 9 (second embodiment) , which represents a substantial improvement over the first and second embodiments of the process and over the standard sequence.

It should be noted that limiting the speed of rotation of the wafer when the position of a collector 40 is changed could be implemented independently of the synchronization of the dispensing over the front face 1a and over the back face 1b and/or independently of the optimization of the dispensing of the first solution over the front face 1a in the form of a spray.

The process according to the present disclosure is particularly suitable for treating SOI substrates featuring thin (silicon and oxide) layers of less than 50 nm in thickness, and in particular substrates in which the silicon surface layer is less than 20 nm in thickness.

Of course, the present disclosure is not limited to the described embodiments and examples, and variant embodiments may be introduced thereinto without departing from the scope of the present disclosure as defined by the claims.

What is claimed is:

1. A method of treating an SOI substrate in a single wafer cleaner, comprising:
gripping and rotating the substrate using a system; and
dispensing a first liquid solution from a first nozzle in the form of a spray of droplets onto a front face of the SOI substrate;
wherein the kinetic energy per unit area of the droplets is lower than or equal to 30 joules/m².

2. The method of claim 1, wherein the spray comprises a mixture of the first liquid solution and nitrogen gas, the first liquid solution flowing from the first nozzle at a flow rate of between 0.1 liter per minute and 0.2 liter per minute, the nitrogen gas flowing from the nozzle first at a flow rate of less than or equal to 70 liters per minute.

3. The method of claim 1, wherein the first liquid solution flows from the first nozzle at a flow rate of between 0.15 liter per minute and 0.2 liter per minute, and the nitrogen gas flows from the first nozzle at a flow rate less than or equal to 60 liters per minute

4. The method of claim 1, further comprising dispensing a second solution from a second nozzle onto a back face of the SOI substrate.

5. The method of claim 4, wherein the dispensing of the second solution from the second nozzle onto the back face of the SOI substrate is performed only when the front face of the SOI substrate is protected via the dispensing of the first liquid solution onto the front face of the SOI substrate or via formation of a nitrogen cushion on the front face of the SOI substrate.

6. The method of claim 5, wherein the dispensing of the second solution from the second nozzle onto the back face of the SOI substrate is performed only when the front face of the SOI substrate is protected via the formation of the nitrogen cushion on the front face of the SOI substrate, the nitrogen cushion being formed between the front face of the SOI substrate and a screen plate positioned parallel to the front face, the screen plate dispensing nitrogen under pressure.

7. The method of claim 4, further comprising dispensing a third solution in the form of a low-pressure or medium-pressure liquid jet onto the front face of the SOI substrate.

8. The method of claim 7, wherein the dispensing of the second solution from the second nozzle onto the back face of the SOI substrate is performed only when the front face of the SOI substrate is protected via the dispensing of the first solution or the third solution onto the front face of the SOI substrate, or via the formation of a nitrogen cushion on the front face of the SOI substrate.

9. The method of claim 8, wherein the dispensing of the second solution from the second nozzle onto the back face of the SOI substrate is performed only when the front face of the SOI substrate is protected via the formation of the nitrogen cushion on the front face of the SOI substrate, the nitrogen cushion being formed between the front face of the SOI substrate and a screen plate positioned parallel to the front face, the screen plate dispensing nitrogen under pressure.

10. The method of claim 5, wherein the dispensing of the second solution from the second nozzle onto the back face of the SOI substrate is synchronized with the dispensing of the first liquid solution from the first nozzle onto a front face of the SOI substrate.

11. The method of claim 1, further comprising collecting the dispensed first liquid solution using a plurality of tapered collectors arranged in a space peripheral to the SOI substrate, and changing a position of each collector only when a rotational speed of the SOI substrate is lower than or equal to 600 revolutions per minute.
